(19) United States
(12) Patent Application Publication
(10) Pub. No.: US 2026/0007042 A1
(43) Pub. Date: Jan. 1, 2026

(54) DISPLAY DEVICE

(71) Applicant: Samsung Display Co., Ltd., Yongin-Si (KR)

(72) Inventors: OHJUNE KWON, Yongin-si (KR); WOO YONG SUNG, Yongin-si (KR)

(21) Appl. No.: 19/210,196

(22) Filed: May 16, 2025

(30) Foreign Application Priority Data
Jun. 28, 2024 (KR) 10-2024-0084943

(51) Int. Cl. H10K 59/80; H10K 102/00

(52) U.S. Cl. CPC H10K 59/8722; H10K 59/873; H10K 2102/351

(57) ABSTRACT

A display device includes a base layer including a display region and a non-display region adjacent to the display region, a crack dam disposed on the base layer, spaced apart from a boundary between the display region and the non-display region in a direction away from the display region, and facing the boundary between the display region and the non-display region, an encapsulation layer disposed on the base layer and covering the crack dam, a first insulating layer disposed on the encapsulation layer, a protrusion pattern disposed on the first insulating layer and extending from the boundary between the display region and the non-display region to an end of the non-display region in the direction away from the display region, and a second insulating layer disposed on the first insulating layer and covering the protrusion pattern.

### CROSS-REFERENCE TO RELATED APPLICATIONS

This application claims priority under 35 U.S.C. § 119 to Korean Patent Application No. 10-2024-0084943, filed on Jun. 28, 2024, the entire contents of which are incorporated herein by reference.

### BACKGROUND

The present disclosure relates to a display device having improved adhesion reliability.

Display devices such as televisions, monitors, smartphones, and tablets, which provide images to a user, include a display panel that displays images. Various types of display panels, such as a liquid crystal display panel, an organic light-emitting display panel, an electro wetting display panel, or an electrophoretic display panel, are being developed. Much research is being conducted to improve reliability in a manufacturing process of the display panel.

### SUMMARY

The present disclosure provides a display device with improved adhesion reliability.

According to an embodiment of the present disclosure, a display device includes a base layer including a display region and a non-display region adjacent to the display region, a crack dam disposed above the base layer, spaced apart from a boundary between the display region and the non-display region in a direction away from the display region, and facing the boundary between the display region and the non-display region, an encapsulation layer disposed on the base layer and covering the crack dam, a first insulating layer disposed on the encapsulation layer, a protrusion pattern disposed on the first insulating layer and extending from the boundary between the display region and the non-display region to an end of the non-display region in the direction away from the display region, and a second insulating layer disposed on the first insulating layer and covering the protrusion pattern.

In an embodiment, an end of the protrusion pattern may be spaced further apart from the boundary between the display region and the non-display region than the crack dam.

In an embodiment, the protrusion pattern may include an organic material.

In an embodiment, the protrusion pattern may be provided in plurality, and a plurality of protrusion patterns may extend from a center of the display region to the end of the non-display region in a radial direction.

In an embodiment, the protrusion pattern may extend from a center of the display region in the direction away from the display region, and the crack dam may extend in a direction crossing a direction in which the protrusion pattern extends.

In an embodiment, the thickness of the protrusion pattern may be greater than the thickness of the crack dam.

In an embodiment, an end of the first insulating layer, an end of the protrusion pattern, and an end of the second insulating layer may be aligned with each other.

In an embodiment, the display device may further include a planarization film disposed on the second insulating layer.

In an embodiment, at least a portion of the planarization film may be recessed from an end of the second insulating layer toward the display region.

In an embodiment, an end of the protrusion pattern may be recessed from the ends of the first and second insulating layers toward the display region.

In an embodiment, the encapsulation layer may include a first inorganic layer, an organic layer, and a second inorganic layer sequentially disposed above the base layer. The organic layer may extend from the display region to a dam disposed in the non-display region, and the first inorganic layer and the second inorganic layer may extend from a region overlapping the dam in the direction away from the display region and may be in contact with each other.

In an embodiment, the display device may further include a circuit element layer including a first element insulating layer disposed on the base layer and a second element insulating layer disposed on the first element insulating layer. The crack dam may be disposed on the first element insulating layer and the second element insulating layer and cover an end of the second element insulating layer.

According to an embodiment of the present disclosure, a display device includes a base layer including a display region and a non-display region adjacent to the display region, a plurality of protrusion patterns disposed in the non-display region of the base layer and extending from a boundary between the display region and the non-display region in a direction away from the display region, and a plurality of crack dams disposed in the non-display region of the base layer and extending in a direction that crosses a direction in which the plurality of protrusion patterns extends.

In an embodiment, the plurality of protrusion patterns may extend in a radial direction on a plane.

In an embodiment, ends of the plurality of protrusion patterns may be spaced further apart from the boundary between the display region and the non-display region than the plurality of crack dams.

In an embodiment, the plurality of crack dams and the plurality of protrusion patterns may be alternately arranged in a direction parallel to the boundary between the display region and the non-display region.

In an embodiment, the display device may further include an encapsulation layer disposed on the base layer. Ends of the plurality of protrusion patterns may be recessed from an end of the encapsulation layer toward the display region.

In an embodiment, the display device may further include a circuit element layer disposed on the base layer, an encapsulation layer disposed on the circuit element layer, a first insulating layer disposed on the encapsulation layer, a second insulating layer disposed on the first insulating layer and covering the plurality of protrusion patterns, and a planarization film disposed on the second insulating layer.

In an embodiment, the circuit element layer may include a first element insulating layer disposed on the base layer and a second element insulating layer disposed on the first element insulating layer. The plurality of crack dams may be disposed on the first element insulating layer and the second element insulating layer and cover an end of the second element insulating layer.

According to an embodiment of the present disclosure, an electronic device includes a processor providing input image data, and a display device displaying an image in response to the input image data. The display device may include a base layer comprising a display region and a non-display region adjacent to the display region, a plurality of crack dams disposed on the base layer, spaced apart from a boundary between the display region and the non-display region in a direction away from the display region, and facing the boundary between the display region and the non-display region, an encapsulation layer disposed on the base layer and covering the plurality of crack dams, a first insulating layer disposed on the encapsulation layer, a plurality of protrusion patterns disposed on the first insulating layer and extending from the boundary between the display region and the non-display region to an end of the non-display region in the direction away from the display region, and a second insulating layer disposed on the first insulating layer and covering the plurality of protrusion patterns.

### BRIEF DESCRIPTION OF THE DRAWINGS

The accompanying drawings are included to provide a further understanding of the present disclosure, and illustrate an embodiment of the present disclosure, together with the following description, to explain the features of the present disclosure.

FIG. 1 is a perspective view of a display device according to an embodiment of the present disclosure.

FIG. 2 is an exploded perspective view of the display device according to an embodiment of the present disclosure.

FIG. 3 is a cross-sectional view of a display module according to an embodiment of the present disclosure.

FIG. 4 is a cross-sectional view of an input sensor and an encapsulation layer according to an embodiment of the present disclosure.

FIG. 5A illustrates a display panel prior to being cut during a manufacturing process of the display panel according to an embodiment of the present disclosure.

FIG. 5B illustrates a display panel after being cut during a manufacturing process of the display panel according to an embodiment of present disclosure.

FIG. 6 is an enlarged perspective view of a region corresponding to AA′ in FIG. 5B.

FIG. 7 is a cross-sectional view taken along a line I-I′ of FIG. 6.

FIG. 8 is a cross-sectional view taken along a line II-II′ of FIG. 6.

FIG. 9 is a cross-sectional view taken along a line II-II′ of FIG. 6.

### DETAILED DESCRIPTION

In this specification, it will be understood that when an element (or region, layer, portion, etc.) is referred to as being “on”, “connected to” or “coupled to” another element, it can be directly on, connected or coupled to the other element, or indirectly on, connected or coupled to the other element with an intervening element therebetween.

Like reference numerals refer to like elements throughout this specification. In addition, in the drawings, the thicknesses, ratios, and dimensions of elements are exaggerated for effective description of the technical contents. As used herein, the term “and/or” includes any and all combinations that the associated configurations can define.

It will be understood that, although the terms first, second, etc. may be used herein to describe various elements, these elements should not be limited by these terms. These terms are only used to distinguish one element from another element. For example, a first element could be referred to as a second element without departing from the scope of the present invention. Similarly, the second element may also be referred to as the first element. The terms of a singular form include plural forms unless clearly indicated otherwise.

In addition, terms, such as “below”, “lower”, “above”, “upper” or the like, are used herein for ease of description to describe the spatial relation between one element and other element(s) as illustrated in the drawings. The above terms are relative concepts and are described based on the directions indicated in the drawings.

It will be understood that the terms “include” and/or “have”, when used in this specification, specify the presence of stated features, integers, steps, operations, elements, components and/or groups thereof, but do not preclude the presence or addition of one or more other features, integers, steps, operations, elements, components, and/or groups thereof.

Unless defined otherwise, all terms (including technical and scientific terms) used herein have the same meaning as commonly understood by one of ordinary skill in the art to which the present disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, an embodiment of the present disclosure will be described with reference to the drawings.

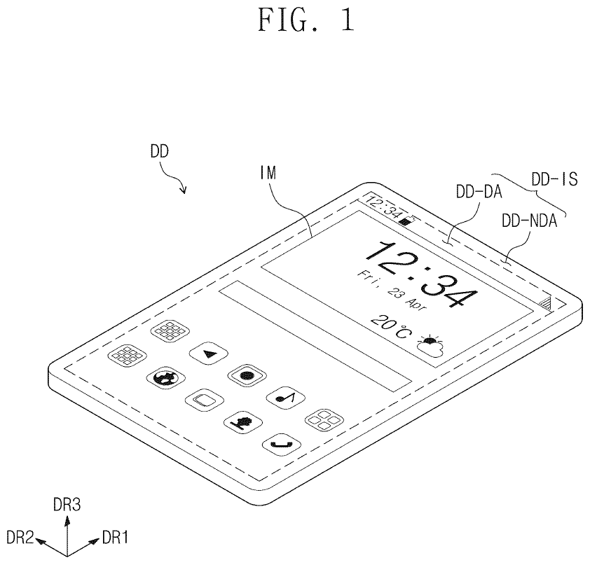

FIG. 1 is a perspective view of a display device DD according to an embodiment of the present disclosure.

In an embodiment of the present disclosure, the display device DD may be activated in response to an electrical signal received from a host or a processor. For example, the display device DD may be a large-sized electronic device such as a television, a monitor, or an outdoor billboard. In addition, the display device DD may be a small or medium-sized electronic device such as a personal computer, a laptop computer, a personal digital terminal, a car navigation unit, a game console, a smartphone, a tablet, or a camera. However, these are examples, and the display device DD may be applied to other electronic devices as long as they do not depart from the scope of the present disclosure. As an example, FIG. 1 illustrates the display device DD as a display device in a smartphone.

Referring to FIG. 1, the display device DD may display an image IM, in response to an input image data from the host or the processor, through a display surface DD-IS. A clock window and a plurality of icons may be illustrated as an example of the image IM. The display surface DD-IS may be parallel to a plane defined by a first direction DR1 and a second direction DR2. The display device DD may display an image IM on the display surface DD-IS toward a normal direction of the display surface DD-IS. The normal direction of the display surface DD-IS may indicate a third direction DR3.

The display surface DD-IS may include a display region DD-DA in which an image IM is displayed and a non-display region DD-NDA adjacent to the display region DD-DA. The non-display region DD-NDA may be a region in which an image IM is not displayed. The non-display region DD-NDA may be adjacent to any one side of the display region DD-DA or may be omitted.

In FIG. 1, the display surface DD-IS is illustrated to have a planar shape, but the display surface DD-IS may have a concavely or convexly curved shape with respect to a plane whose normal direction is the third direction DR3. For example, the edges of the display surface DD-IS may have curved shapes with predetermined curvatures. The curvatures of the edges may be the same as or different from each other. For example, the display surface DD-IS may include a plurality of side surfaces that display an image. The plurality of side surfaces may include a first to a fourth side surfaces.

In an embodiment, the front (or upper) and rear (or lower) surfaces of the display device DD may be defined based on a direction in which an image IM is displayed. The front and rear surfaces may face each other in the third direction DR3, and the normal direction of each of the front and rear surfaces may be parallel to the third direction DR3. Directions indicated by the first to third directions DR1, DR2, and DR3 are relative concepts and may be converted into other directions. In the present disclosure, the expression “on a plane” may mean when viewed from the third direction DR3.

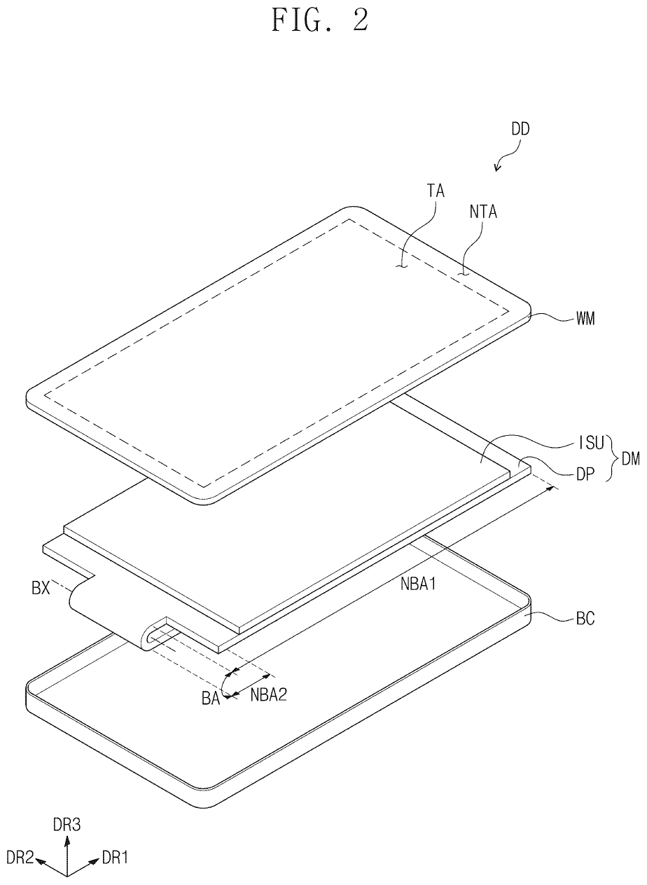

FIG. 2 is an exploded perspective view of the display device DD according to an embodiment of the present disclosure.

Referring to FIG. 2, the display device DD may include a window WM, a display module DM, and a housing member BC. The display device DD may further include an optical member disposed between the window WM and the display module DM. The optical member may include a polarizer.

The window WM may be disposed on the display module DM and transmit an image, which is provided from the display module DM, to the outside. The window WM may include a transmission region TA and a non-transmission region NTA. The transmission region TA may overlap the display region DD-DA (see FIG. 1) and have a shape corresponding to the display region DD-DA.

The window WM may include an optically transparent insulating material, and the window WM may include glass or plastic. The window WM may have a multi-layered structure or a single-layered structure. For example, the window WM may include a plurality of plastic films bonded to each other with an adhesive, or may include a glass substrate and a plastic film bonded to each other with an adhesive. In FIG. 2, the window WM is illustrated to have a planar shape, but is not limited thereto. The edges of the window WM may have predetermined curvatures. The curvatures of the edges may be the same as or different from each other.

The non-transmission region NTA may overlap the non-display region DD-NDA (see FIG. 1) and have a shape corresponding to the non-display region DD-NDA. The non-transmission region NTA may have a relatively low light transmittance compared to the transmission region TA. The non-transmission region NTA may be defined by a bezel pattern disposed in a portion of the base layer of the window WM, and a region in which the bezel pattern is not disposed may be defined as the transmission region TA. However, an embodiment of the present invention is not limited thereto, and the non-transmission region NTA may be omitted.

The display module DM may be disposed below the window WM. The display module DM may be a component that generates an image IM. The image IM generated by the display module DM may be displayed on the display surface DD-IS of the display module DM and may be viewed by a user from the outside through the transmission region TA. The display module DM may include a display panel DP and an input sensor ISU.

According to an embodiment of the present disclosure, the display panel DP may be any one of a liquid crystal display panel, an electrophoretic display panel, a microelectromechanical system (MEMS) display panel, an electrowetting display panel, an organic light-emitting display panel, an inorganic light-emitting display panel, or a quantum dot light-emitting display panel. However, the display panel DP is not limited thereto. Hereinafter, the display panel DP may be described as an organic light-emitting display panel.

The input sensor ISU may include any one of a capacitive sensor, an optical sensor, an ultrasonic sensor, or an electromagnetic induction sensor. The input sensor ISU may be disposed directly on the display panel DP. As used herein, the expression “component A is disposed directly on component B” means that no adhesive layer or no intermediate layer is disposed between component A and component B. The input sensor ISU may be disposed on the display panel DP through a continuous process. The input sensor ISU may be manufactured separately and attached to the upper side of the display panel DP by an adhesive layer. However, an embodiment of the present disclosure is not limited thereto.

The display panel DP according to an embodiment of the present disclosure may include a bending region BA, a first non-bending region NBA1 and a second non-bending region NBA2 arranged to be spaced apart from each other in the first direction DR1 with the bending region BA interposed therebetween. The bending region BA may be defined as a region in which the display panel DP is bent along a virtual bending axis BX extending in the second direction DR2. The first non-bending region NBA1 may be defined as a region overlapping the transmission region TA, and the second non-bending region NBA2 may be defined as a region in contact with a circuit board.

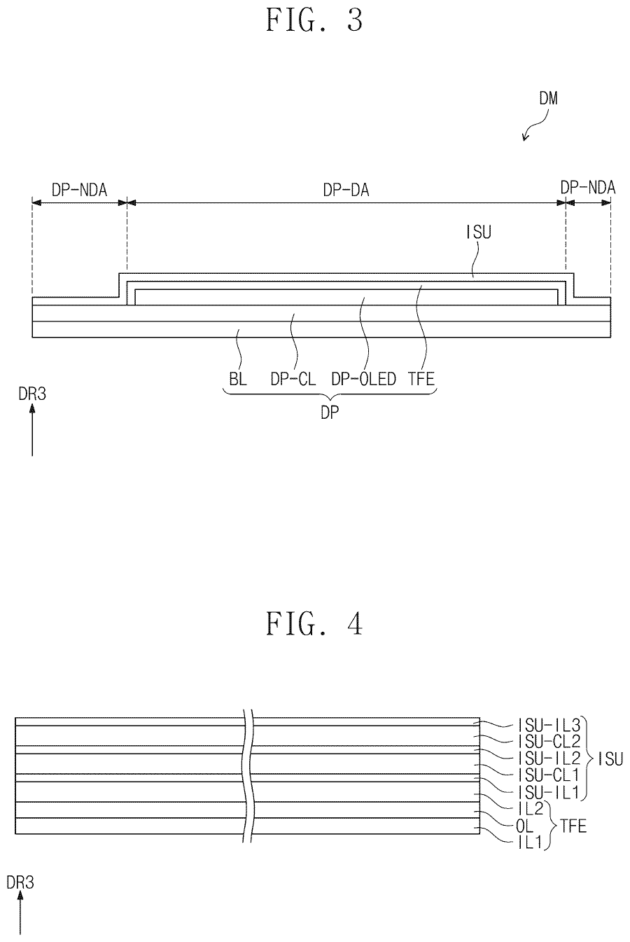

FIG. 3 is a cross-sectional view of a display module DM according to an embodiment of the present disclosure. In explaining FIG. 3, descriptions will be provided with reference to FIGS. 1 and 2, and redundant descriptions as indicated by the same reference numerals may be omitted.

Referring to FIG. 3, the display panel DP may include a base layer BL, a circuit element layer DP-CL disposed on the base layer BL, a display element layer DP-OLED, and an encapsulation layer TFE. The input sensor ISU may be disposed on the encapsulation layer TFE.

The display panel DP may include a display region DP-DA and a non-display region DP-NDA. The display region DP-DA of the display panel DP may correspond to the display region DD-DA illustrated in FIG. 1 or the transmission region TA illustrated in FIG. 2, and the non-display region DP-NDA may correspond to the non-display region DD-NDA illustrated in FIG. 1 or the non-transmission region NTA illustrated in FIG. 2.

The base layer BL may include a synthetic resin film. The base layer BL may have a multi-layered structure. For example, the base layer BL may have a three-layer structure including a synthetic resin layer, an inorganic layer, and a synthetic resin layer. The synthetic resin layer may be a polyimide-based resin layer, but the material of the base layer BL according to an embodiment is not limited thereto. For example, the base layer BL may include a glass substrate, a metal substrate, or an organic/inorganic composite material substrate.

The circuit element layer DP-CL may include at least one insulating layer and a circuit element. The insulating layer may include at least one inorganic layer or at least one organic layer. The circuit element may include signal lines, pixel driving circuits, or the like.

The display element layer DP-OLED may include a plurality of organic light-emitting diodes. The display element layer DP-OLED may further include an organic layer.

The encapsulation layer TFE may seal the display element layer DP-OLED. For example, the encapsulation layer TFE may include a thin film encapsulation layer. The thin film encapsulation layer may include a stacked structure including a first inorganic layer, an organic layer and a second inorganic layer. The encapsulation layer TFE may protect the display element layer DP-OLED from moisture, oxygen, or foreign substances such as dust particles. Without being limited thereto, however, the encapsulation layer TFE may further include an additional insulating layer besides the thin film encapsulation layer. For example, the encapsulation layer TFE may further include an optical insulating layer to control a refractive index.

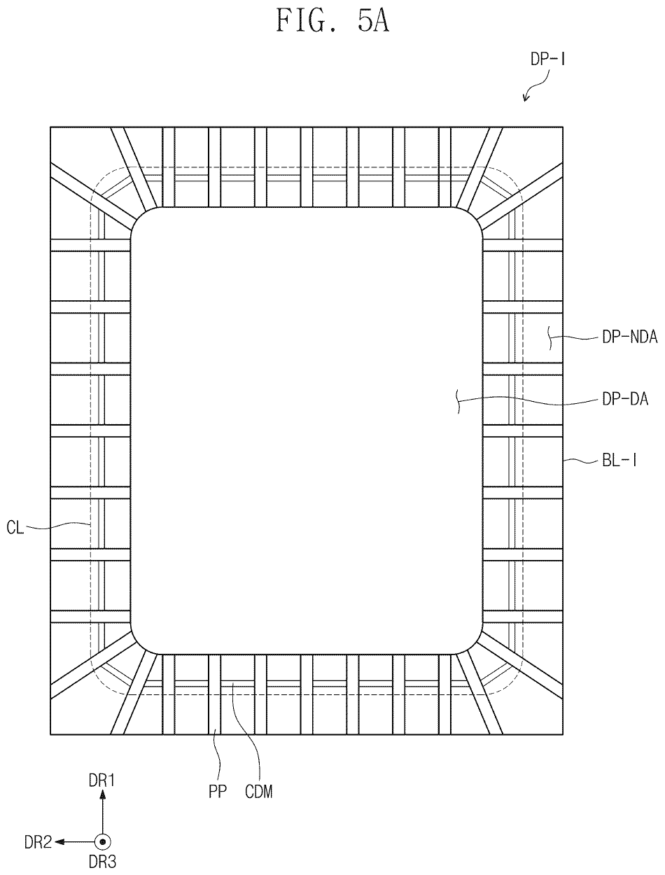

FIG. 4 is a cross-sectional view of an input sensor ISU and an encapsulation layer TFE according to an embodiment of the present disclosure.

Referring to FIG. 4, the encapsulation layer TFE may include a first inorganic film IL1, an organic film OL, and a second inorganic film IL2 which are sequentially stacked, but the films included in the encapsulation layer TFE are not limited thereto. The first inorganic film IL1 and the second inorganic film IL2 may protect the display element layer DP-OLED from moisture and oxygen, and the organic film OL may protect the display element layer DP-OLED from foreign substances such as dust particles. The first inorganic film IL1 and the second inorganic film IL2 may include a silicon nitride layer, a silicon oxynitride layer, a silicon oxide layer, a titanium oxide layer, an aluminum oxide layer, or the like. The organic film OL may include, but is not limited to, an acrylic-based organic layer.

The input sensor ISU may include a first sensing insulating layer ISU-IL1, a first conductive layer ISU-CL1, a second sensing insulating layer ISU-IL2, a second conductive layer ISU-CL2, and a third sensing insulating layer ISU-IL3. The first sensing insulating layer ISU-IL1 may be disposed directly on the encapsulation layer TFE. However, this is an example, and an embodiment of the present disclosure is not limited thereto.

Each of the first conductive layer ISU-CL1 and the second conductive layer ISU-CL2 may have a single-layered structure or a multi-layered structure in which layers are stacked along the third direction DR3. The conductive layers having a multi-layered structure may include at least one of a transparent conductive layer or a metal layer. The transparent conductive layer may include indium tin oxide (ITO), indium zinc oxide (IZO), zinc oxide (ZnO), indium tin zinc oxide (ITZO), PEDOT, metal nanowire, or graphene, and the metal layer may include molybdenum, silver, titanium, copper, aluminum, or alloys thereof. The conductive layer having a multi-layered structure may include metal layers containing different metals. For example, at least any one of the first conductive layer ISU-CL1 and the second conductive layer ISU-CL2 may have a three-layer metal structure, for example, a three-layer structure of titanium/aluminum/titanium. A metal with relatively high durability and low reflectance may be applied to an outer layer, and a metal with high electrical conductivity may be applied to an inner layer.

Each of the first conductive layer ISU-CL1 and the second conductive layer ISU-CL2 may include a plurality of conductive patterns. The first conductive layer ISU-CL1 may include first conductive patterns, and the second conductive layer ISU-CL2 may include second conductive patterns. Each of the first conductive patterns and the second conductive patterns may include sensing electrodes and signal lines connected thereto. The sensing electrodes of the first conductive patterns and the sensing electrodes of the second conductive patterns may be insulated from and cross each other.

Each of the first to third sensing insulating layers ISU-IL1, ISU-IL2, and ISU-IL3 may include an inorganic layer or an organic layer. In an embodiment, the first sensing insulating layer ISU-IL1 and the second sensing insulating layer ISU-IL2 may include an inorganic layer, and the third sensing insulating layer ISU-IL3 may include an organic layer. However, this is an example, and any one of the first to third sensing insulating layers ISU-IL1, ISU-IL2, and ISU-IL3 of the input sensor ISU may be omitted.

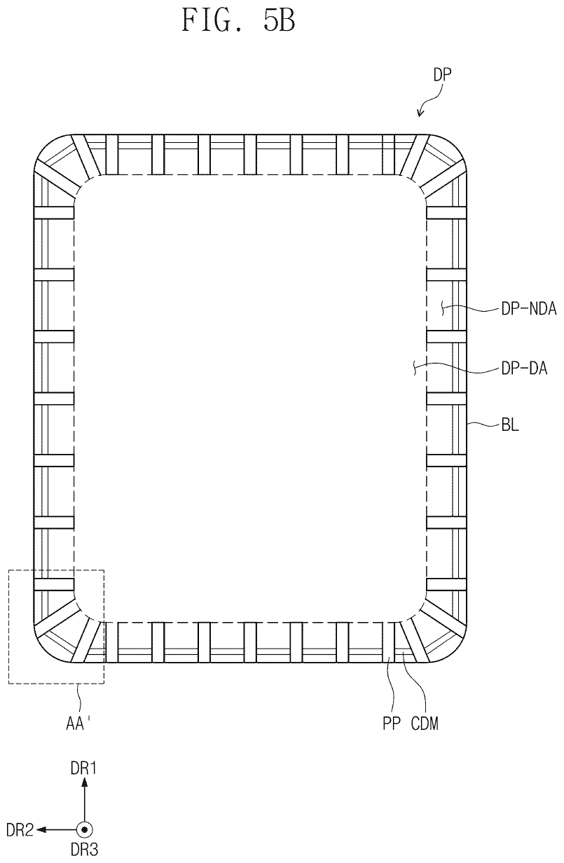

FIG. 5A illustrates a display panel DP-I before being cut during a manufacturing process of the display panel DP-I according to an embodiment of the present disclosure. For the convenience of explanation, FIG. 5A mainly illustrates a base layer BL-I, a protrusion pattern PP, a crack dam CDM, and a cutting line CL.

Referring to FIG. 5A, the display panel DP-I (hereinafter referred to as a preliminary display panel) before being cut may include a display region DP-DA and a non-display region DP-NDA. The protrusion pattern PP and the crack dam CDM may be disposed in the non-display region DP-NDA. A line for cutting the preliminary display panel DP-I during a manufacturing process of the display panel may be defined as the cutting line CL. That is, the preliminary display panel DP-I may be cut along the cutting line CL. The cutting line CL may be formed in the non-display region DP-NDA. The cutting line CL may be formed at a certain distance from a boundary between the display region DP-DA and the non-display region DP-NDA. The cutting line CL may cross a direction in which the protrusion pattern PP, which will be described later, extends.

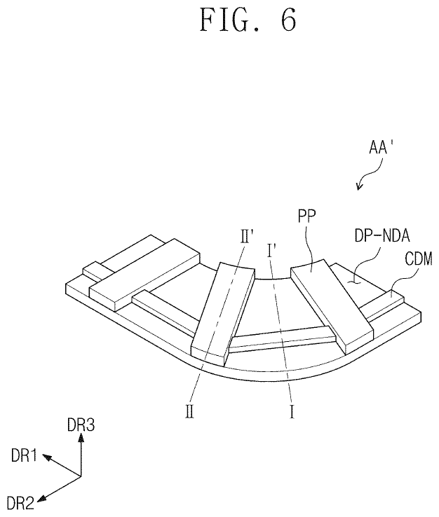

FIG. 5B illustrates a display panel DP after being cut during the manufacturing process of the display panel according to an embodiment of the present disclosure. FIG. 6 is an enlarged perspective view of a region corresponding to AA′ in FIG. 5B.

In explaining FIGS. 5B and 6, descriptions will be provided with reference to FIGS. 1 to 5A, and redundant descriptions as indicated by the same reference numerals may be omitted. For the convenience of explanation, the protrusion pattern PP and the crack dam CDM are mainly illustrated in FIG. 5B.

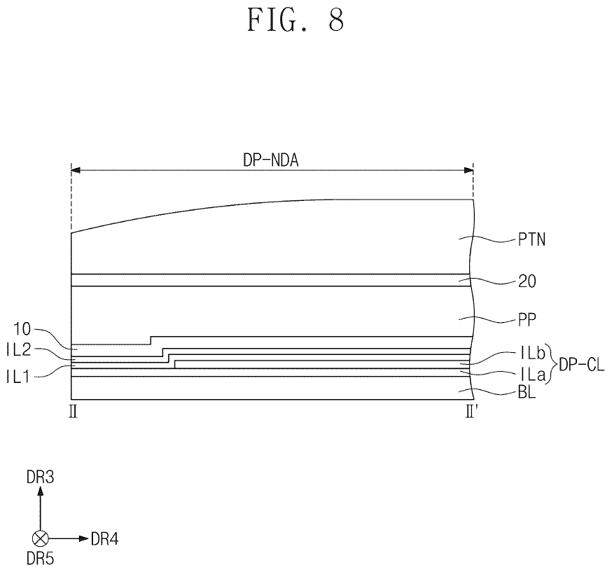

Referring to FIGS. 5B and 6, the protrusion pattern PP may be disposed on the base layer BL. For example, the protrusion pattern PP may have a shape that protrudes from a first insulating layer 10 (see FIG. 8) in the thickness direction of the base layer BL. The protrusion pattern PP may be disposed in the non-display region DP-NDA. The protrusion pattern PP may extend from the boundary between the display region DP-DA and the non-display region DP-NDA toward a direction away from the display region DP-DA. That is, the protrusion pattern PP may extend from the center of the display region DP-DA toward a direction away from the display region DP-DA. The protrusion pattern PP may be disposed to extend in a direction perpendicular to the boundary between the display region DP-DA and the non-display region DP-NDA. For example, when the boundary between the display region DP-DA and the non-display region DP-NDA has a curved shape, the protrusion pattern PP may be disposed to extend in a direction perpendicular to the tangent line of the boundary between the display region DP-DA and the non-display region DP-NDA.

The display panel DP may include a plurality of protrusion patterns PP. The plurality of protrusion patterns PP may extend in radial directions from the center of the display region DP-DA to an end of the non-display region DP-NDA. In other words, the plurality of protrusion patterns PP may extend in radial directions on a plane.

The plurality of protrusion patterns PP may be disposed to surround the boundary between the display region DP-DA and the non-display region DP-NDA. The plurality of protrusion patterns PP may be disposed to be spaced apart from each other at regular intervals in the non-display region DP-NDA. As an example, FIG. 5B illustrates 36 protrusion patterns PP, but the number of the protrusion patterns PP is not limited thereto. The number of the protrusion patterns PP may be varied in various ways according to the size of the display panel DP and a display panel processing method. The distance between the plurality of protrusion patterns PP may be varied in various ways according to the size of the display panel DP and the display panel processing method.

The crack dam CDM may be disposed on the base layer BL. The crack dam CDM may be spaced apart from the boundary between the display region DP-DA and the non-display region DP-NDA in a direction away from the display region DP-DA. The crack dam CDM may face the boundary between the display region DP-DA and the non-display region DP-NDA. The thickness of the crack dam CDM may be smaller than the thickness of the protrusion pattern PP. In other words, the thickness of the protrusion pattern PP may be greater than the thickness of the crack dam CDM.

The display panel DP may include a plurality of crack dams CDM. The plurality of crack dams CDM may extend in a direction that crosses the direction in which the protrusion pattern PP extends. For example, when the protrusion pattern PP extends in a first reference direction, each of the plurality of crack dams CDM may extend in a second reference direction that crosses the first reference direction, and the plurality of crack dams CDM may be disposed to be spaced apart from each other in the second reference direction.

The plurality of protrusion patterns PP may include an end adjacent to the display region DP-DA and an end adjacent to the edge of the display panel DP. The ends of the plurality of protrusion patterns PP adjacent to the edge of the display panel DP may be spaced further apart from the boundary between the display region DP-DA and the non-display region DP-NDA than the plurality of crack dams CDM. The plurality of crack dams CDM and the plurality of protrusion patterns PP may be alternately arranged in a direction parallel to the boundary between the display region DP-DA and the non-display region DP-NDA. In other words, one protrusion pattern PP may be disposed between two adjacent crack dams CDM among the plurality of crack dams CDM, and one crack dam CDM may be disposed between two adjacent protrusion patterns PP among the plurality of protrusion patterns PP.

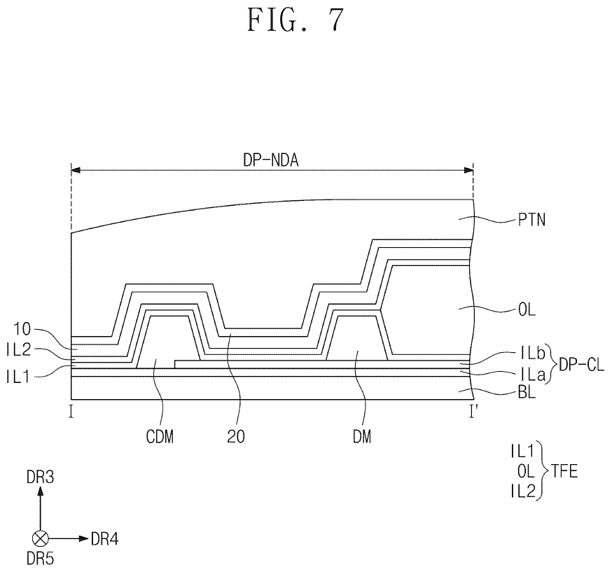

FIG. 7 is a cross-sectional view taken along a line I-I′ of FIG. 6, and FIG. 8 is a cross-sectional view taken along a line II-II′ of FIG. 6. In explaining FIGS. 7 and 8, descriptions will be provided with reference to FIGS. 1 to 6, and redundant descriptions as indicated by the same reference numerals may be omitted. A fourth direction DR4 and a fifth direction DR5 in FIG. 7 may be defined as directions between the first direction DR1 (see FIG. 5B) and the second direction DR2 (see FIG. 5B). A plane formed by the fourth direction DR4 and the fifth direction DR5 may be the same plane as a plane formed by the first direction DR1 and the second direction DR2.

Referring to FIGS. 6 to 8, the display panel DP may include a base layer BL, a circuit element layer DP-CL, an encapsulation layer TFE, a dam DM, a crack dam CDM, a first insulating layer 10, a second insulating layer 20, and a planarization film PTN.

The circuit element layer DP-CL may include a first element insulating layer ILa disposed on the base layer BL and a second element insulating layer ILb disposed on the first element insulating layer ILa.

FIG. 7 illustrates only the first element insulating layer ILa and the second element insulating layer ILb among a plurality of elements of the circuit element layer DP-CL, but a conductive pattern and a semiconductor pattern may be additionally disposed between the first element insulating layer ILa and the second element insulating layer ILb. For example, in a manufacturing step of the display panel DP, an insulating layer, a semiconductor layer, and a conductive layer may be formed on the base layer BL by coating, deposition, or the like. Hereafter, the insulating layer, the semiconductor layer, and the conductive layer may be selectively patterned by a photolithography method. Through these processes, a semiconductor pattern, a conductive pattern, a signal line, or the like included in the circuit element layer DP-CL may be formed.

The dam DM may be disposed in the display region DP-DA or in the non-display region DP-NDA. The dam DM may prevent liquid organic substances from overflowing.

The crack dam CDM may be disposed on the first element insulating layer ILa and the second element insulating layer ILb, and may cover an end, including a side surface, of the second element insulating layer ILb. As the crack dam CDM is disposed on the first element insulating layer ILa and the second element insulating layer ILb, the crack dam CDM may be more effectively coupled to the circuit element layer DP-CL, thereby reducing crack propagation.

The encapsulation layer TFE may be disposed on the circuit element layer DP-CL disposed on the base layer BL. The encapsulation layer TFE may cover the crack dam CDM and the dam DM. The encapsulation layer TFE may include a first inorganic film IL1, an organic film OL, and a second inorganic film IL2 sequentially disposed above the base layer BL. FIG. 7 illustrates that the encapsulation layer TFE includes two inorganic films and one organic film, but an embodiment of the present disclosure is not limited thereto. For example, the encapsulation layer TFE may include three inorganic films and two organic films, in which case each of the inorganic films and the organic films may be alternately stacked.

The first inorganic film IL1 may be disposed on the circuit element layer DP-CL. The first inorganic film IL1 may include an inorganic material. The first inorganic film IL1 may cover the dam DM and the crack dam CDM and extend to an end of the base layer BL. In order to control the flow of an organic material which is applied on the first inorganic film IL1, a hydrophobic or hydrophilic plasma treatment may be performed on the first inorganic film IL1.

The organic film OL may be disposed on the first inorganic film IL1. The organic film OL may extend from the display region DP-DA to the dam DM disposed in the non-display region DP-NDA. The organic film OL may protect a light-emitting element from foreign substances such as dust particles. For example, the organic film OL may include an acrylic-based resin, but the material thereof is not limited to the above example. The organic film OL may be formed by providing a liquid polymer resin on the first inorganic film IL1 and curing the liquid polymer resin. The liquid polymer resin may be formed by a vapor deposition, printing, or slit coating method, but an embodiment of the present disclosure is not limited thereto. In an embodiment of the present disclosure, the organic film OL may be formed through an ink-jet process.

The second inorganic film IL2 may be disposed on the organic film OL and the first inorganic film IL1. The second inorganic film IL2 may include an inorganic material. The first inorganic film IL1 and the second inorganic film IL2 may extend from a region overlapping the dam DM in a direction (for example, in a direction opposite to the fourth direction DR4) away from the display region DP-DA and are in contact with each other.

The first insulating layer 10 may be disposed on the encapsulation layer TFE. The first insulating layer 10 may be the first sensing insulating layer ISU-IL1 (see FIG. 4) or the second sensing insulating layer ISU-IL2 (see FIG. 4).

The protrusion pattern PP may be disposed on the first insulating layer 10. The protrusion pattern PP may be disposed between the first and second insulating layers 10 and 20. The protrusion pattern PP may include an organic material.

During a cutting process in the method of manufacturing the display panel DP, film lifting may occur at the cross section of the preliminary display panel DP-I being cut. In addition, when the preliminary display panel DP-I to be cut has a rounded corner shape and an impact is applied to a side of the rounded corner region of the preliminary display panel DP-I to be cut, lifting may occur in films disposed above. For example, the planarization film PTN may be peeled off from the second insulating layer 20 due to repulsive force applied to the display panel DP.

As the protrusion pattern PP includes an organic material, bonding force between the first insulating layer 10 and the protrusion pattern PP and bonding force between the protrusion pattern PP and the second insulating layer 20 may be greater than bonding force between the first insulating layer 10 and the second insulating layer 20. Accordingly, when the display panel DP includes the protrusion pattern PP between the first insulating layer 10 and the second insulating layer 20, a phenomenon, in which the planarization film PTN is peeled off from the second insulating layer 20 in the display panel DP, may be reduced.

In addition, the protrusion pattern PP according to an embodiment of the present disclosure may be formed to extend from the boundary between the display region DP-DA and the non-display region DP-NDA toward the edge of the preliminary display panel DP-I. The protrusion pattern PP may support and bond components, for example, a film or a layer, placed above the protrusion pattern PP and below the protrusion pattern PP across the non-display region DP-NDA of the preliminary display panel DP-I. Accordingly, when the protrusion pattern PP is cut together with the preliminary display panel DP-I during the cutting process, the phenomenon, in which the planarization film PTN is peeled off from the second insulating layer 20, may be reduced.

The second insulating layer 20 may be disposed on the first insulating layer 10. In detail, the second insulating layer 20 may be disposed on the protrusion pattern PP formed on the first insulating layer 10 and cover the protrusion pattern PP. The second insulating layer 20 may be the second sensing insulating layer ISU-IL2 or the third sensing insulating layer ISU-IL3 (see FIG. 4). The planarization film PTN may be disposed on the second insulating layer 20.

An end of the first insulating layer 10, an end of the protrusion pattern PP, and an end of the second insulating layer 20 may be aligned with each other. For example, in a cutting process of the display panel DP, the base layer BL, the display element layer DP-OLED, the encapsulation layer TFE, the first insulating layer 10, the protrusion pattern PP, the second insulating layer 20, and the planarization film PTN may be cut at once. As a result, the cross section of the protrusion pattern PP after cutting may be on the same plane as the cross sections of the base layer BL, the display element layer DP-OLED, the encapsulation layer TFE, the first insulating layer 10, the second insulating layer 20, and the planarization film PTN after being cut. For example, the normal direction of the cross section after cutting is perpendicular to the thickness direction of the base layer BL (e.g., the third direction DR3).

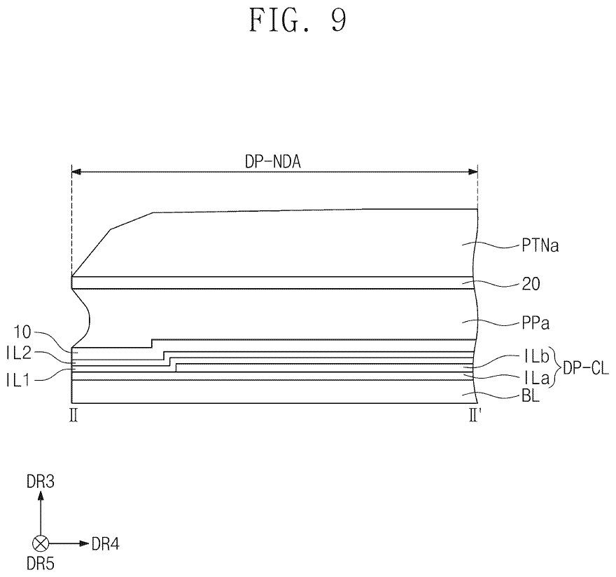

FIG. 9 is a cross-sectional view taken along a line II-II′ of FIG. 6. In describing FIG. 9, the same or similar reference numerals are used for components that are the same as or similar to those described in FIGS. 1 to 8, and duplicate descriptions are omitted.

Referring to FIG. 9, a planarization film PTNa may be made of an organic material. At least a portion of the planarization film PTNa may be recessed from the end of the second insulating layer 20 toward the display region DP-DA (see FIG. 5B). At least a portion of the planarization film PTNa may be recessed from an end of the encapsulation layer TFE (see FIG. 7) toward the display region DP-DA.

A protrusion pattern PPa may be made of an organic material. An end of the protrusion pattern PPa may be recessed from the ends of the first and second insulating layers 10 and 20 toward the display region DP-DA. In other words, the ends of the plurality of protrusion patterns PPa may be recessed from the end of the encapsulation layer TFE toward the display region DP-DA.

Laser cutting may be used in a cutting process of the display panel DP. In this case, the planarization film PTNa and the protrusion pattern PPa containing an organic material may shrink due to heat generated during the cutting process. As a result, a portion of the planarization film PTNa and a portion of the protrusion pattern PPa may be recessed in the direction toward the boundary (e.g., the fourth direction DR4) between the display region DP-DA and the non-display region DP-NDA. If the planarization film PTNa and the protrusion pattern PPa are recessed with respect to a layer containing an inorganic material, the side of the first insulating layer 10, the side of the protrusion pattern PPa, the side of the second insulating layer 20, and the side of the planarization film PTNa may not be aligned with each other. In this case, when an external impact is applied to the display panel DP, the reduction in a surface area directly exposed to the external impact may decrease the repulsive force generated in the planarization film PTNa. Accordingly, a phenomenon, in which the planarization film PTNa is peeled off from the second insulating layer 20, may be reduced or eliminated.

According to an embodiment of the present disclosure as described above, as the protrusion pattern includes an organic material, bonding force between the insulating layer and the protrusion pattern may increase, thereby reducing the phenomenon, in which the planarization film is peeled off from the insulating layer in the display panel.

In addition, the protrusion pattern according to an embodiment of the present disclosure may be formed to extend from the boundary between the display region and the non-display region toward the edge of the display panel. Accordingly, the phenomenon, in which the planarization film is peeled off from the insulating layer when the display panel is cut, may be reduced.

In addition, a portion of the planarization film and a portion of the protrusion pattern according to an embodiment of the present disclosure may be recessed. In this case, when an external impact is applied to the display panel, the reduction in a surface area directly exposed to the external impact may decrease the repulsive force generated in the planarization film PTNa. Accordingly, the phenomenon, in which the planarization film is peeled off from the insulating layer when the display panel is cut, may be reduced or eliminated.

Although the above has been described with reference to an embodiment of the present disclosure, those skilled in the art will appreciate that various modifications and changes can be made to the inventive concept without departing from the scope and spirit of the present disclosure as set forth in the following claims. Accordingly, it is understood that the technical scope of the present disclosure should not be limited to the content described in the detailed description of the specification, but should be determined by the claims described hereinafter.

What is claimed is:

1. A display device comprising:
a base layer comprising a display region and a non-display region adjacent to the display region;
a crack dam disposed on the base layer, spaced apart from a boundary between the display region and the non-display region in a direction away from the display region, and facing the boundary between the display region and the non-display region;
an encapsulation layer disposed on the base layer and covering the crack dam;
a first insulating layer disposed on the encapsulation layer;
a protrusion pattern disposed on the first insulating layer and extending from the boundary between the display region and the non-display region to an end of the non-display region in the direction away from the display region; and
a second insulating layer disposed on the first insulating layer and covering the protrusion pattern.

2. The display device of claim 1, wherein an end of the protrusion pattern is spaced further apart from the boundary between the display region and the non-display region than the crack dam.

3. The display device of claim 1, wherein the protrusion pattern comprises an organic material.

4. The display device of claim 1, wherein the protrusion pattern is provided in plurality, and
a plurality of protrusion patterns extends from a center of the display region to the end of the non-display region in a radial direction.

5. The display device of claim 1, wherein the protrusion pattern extends from a center of the display region in the direction away from the display region, and
the crack dam extends in a direction crossing a direction in which the protrusion pattern extends.

6. The display device of claim 1, wherein the thickness of the protrusion pattern is greater than the thickness of the crack dam.

7. The display device of claim 1, wherein an end of the first insulating layer, an end of the protrusion pattern, and an end of the second insulating layer are aligned with each other.

8. The display device of claim 1, further comprising a planarization film disposed on the second insulating layer.

9. The display device of claim 8, wherein at least a portion of the planarization film is recessed from an end of the second insulating layer toward the display region.

10. The display device of claim 1, wherein an end of the protrusion pattern is recessed from ends of the first and second insulating layers toward the display region.

11. The display device of claim 1, wherein the encapsulation layer comprises a first inorganic layer, an organic layer, and a second inorganic layer sequentially disposed on the base layer,
wherein the organic layer extends from the display region to a dam disposed in the non-display region, and
the first inorganic layer and the second inorganic layer extend from a region overlapping the dam in the direction away from the display region and are in contact with each other.

12. The display device of claim 1, further comprising a circuit element layer comprising a first element insulating layer disposed on the base layer and a second element insulating layer disposed on the first element insulating layer,
wherein the crack dam is disposed on the first element insulating layer and the second element insulating layer and covers an end of the second element insulating layer.

13. A display device comprising:
a base layer comprising a display region and a non-display region adjacent to the display region;
a plurality of protrusion patterns disposed in the non-display region of the base layer and extending from a boundary between the display region and the non-display region in a direction away from the display region; and
a plurality of crack dams disposed in the non-display region of the base layer and extending in a direction that crosses a direction in which the plurality of protrusion patterns extends.

14. The display device of claim 13, wherein the plurality of protrusion patterns extends in a radial direction on a plane.

15. The display device of claim 13, wherein ends of the plurality of protrusion patterns are spaced further apart from the boundary between the display region and the non-display region than the plurality of crack dams.

16. The display device of claim 13, wherein the plurality of crack dams and the plurality of protrusion patterns are alternately arranged in a direction parallel to the boundary between the display region and the non-display region.

17. The display device of claim 13, further comprising an encapsulation layer disposed on the base layer,
wherein ends of the plurality of protrusion patterns are recessed from an end of the encapsulation layer toward the display region.

18. The display device of claim 13, further comprising:
a circuit element layer disposed on the base layer;
an encapsulation layer disposed on the circuit element layer;
a first insulating layer disposed on the encapsulation layer;
a second insulating layer disposed on the first insulating layer and covering the plurality of protrusion patterns; and
a planarization film disposed on the second insulating layer.

19. The display device of claim 18, wherein the circuit element layer comprises a first element insulating layer disposed on the base layer and a second element insulating layer disposed on the first element insulating layer, and
the plurality of crack dams is disposed on the first element insulating layer and the second element insulating layer and cover an end of the second element insulating layer.

20. An electronic device comprising:
a processor providing input image data;
a display device displaying an image in response to the input image data,
wherein the display device comprises:
a base layer comprising a display region and a non-display region adjacent to the display region;
a plurality of crack dams disposed on the base layer, spaced apart from a boundary between the display region and the non-display region in a direction away from the display region, and facing the boundary between the display region and the non-display region;
an encapsulation layer disposed on the base layer and covering the plurality of crack dams;
a first insulating layer disposed on the encapsulation layer;
a plurality of protrusion patterns disposed on the first insulating layer and extending from the boundary between the display region and the non-display region to an end of the non-display region in the direction away from the display region; and
a second insulating layer disposed on the first insulating layer and covering the plurality of protrusion patterns.
